(19) United States
(12) Patent Application Publication
(10) Pub. No.: US 2010/0224238 A1
(43) Pub. Date: Sep. 9, 2010

(54) PHOTOVOLTAIC CELL COMPRISING AN MIS-TYPE TUNNEL DIODE

(75) Inventors: Mohammed M. Hilali, Sunnyvale, CA (US); Christopher J. Petti, Mountain View, CA (US)

Correspondence Address: THE MUELLER LAW OFFICE, P.C., 12951 Harwick Lane, San Diego, CA, 92130, US

(73) Assignee: TWIN CREEKS TECHNOLOGIES, INC., San Jose, CA (US)

(21) Appl. No.: 12/399,065

(22) Filed: Mar. 6, 2009

(51) Int. Cl. H01L 31/00; H01L 21/70

(52) U.S. Cl. 136/255; 438/96; 257/E21.535

(57) ABSTRACT

A photovoltaic cell comprising a thin semiconductor lamina is described; the lamina is formed by cleaving from a donor wafer while the wafer is bonded to a receiver element which provides mechanical support. Thus fabrication steps performed following cleaving are advantageously performed at temperatures that will not damage the receiver element. By fabricating a cell comprising an MIS-type tunnel diode, rather than a conventional p-n diode, a high-temperature doping step may be avoided.

### BACKGROUND OF THE INVENTION

The invention relates to a photovoltaic cell including an MIS-type tunnel diode.

In a photovoltaic cell, incident photons create free charge carriers. An electric field directs these free carriers into current. The electric field most often results from a p-n diode within the photovoltaic cell. A cell including a p-n diode is most economically formed by doping opposing faces of the cell with, respectively, p-type and n-type dopants. The conventional methods of performing these doping steps are performed at high temperature. For some fabrication methods, however, high temperature steps at some point in the process may be disadvantageous.

There is a need, therefore, for a photovoltaic cell that does not operate as a p-n diode which can be fabricated at a lower temperature.

### SUMMARY OF THE PREFERRED EMBODIMENTS

The present invention is defined by the following claims, and nothing in this section should be taken as a limitation on those claims. In general, the invention is directed to a photovoltaic cell operating as an MIS-type tunnel diode, specifically such a cell comprising a thin semiconductor lamina.

A first aspect of the invention provides for a substantially crystalline semiconductor lamina having a first surface and a second surface opposite the first; a transparent conductive oxide; and an insulator layer having a thickness no more than about 40 angstroms, the insulator layer disposed between the lamina and the transparent conductive oxide, wherein the semiconductor lamina is lightly doped to a first conductivity type, the second surface of the lamina is nearer the insulator layer and the first surface of the lamina is farther from the insulator layer, and the first surface of the lamina is heavily doped to the first conductivity type, and wherein, during normal operation of the cell, charge carriers pass between the transparent conductive oxide and the lamina by tunneling through the insulator layer.

Another aspect of the invention provides for a photovoltaic cell comprising a substantially crystalline lamina having a light-facing surface and a back surface, the lamina having a thickness of about 50 microns or less; an insulator layer having a thickness no more than about 40 angstroms, the insulator layer disposed above the light-facing surface of the lamina; and a conductor disposed above the insulator layer and in immediate contact with the insulator layer.

Still another aspect of the invention provides for a photovoltaic cell comprising a substantially crystalline semiconductor lamina having a light-facing surface and a back surface, wherein the lamina is lightly doped to a first conductivity type, and comprises a region at the back surface heavily doped to the first conductivity type; an uninterrupted insulator layer having a thickness no more than about 40 angstroms, the insulator layer disposed above the light-facing surface of the lamina; and a transparent conductive oxide disposed above and in immediate contact with the insulator layer, wherein either the lamina further comprises a region at the light-facing surface heavily doped to a second conductivity type opposite the first, or the photovoltaic cell further comprises a heavily doped semiconductor layer above the light-facing surface of the lamina, the heavily doped semiconductor layer doped to a second conductivity type opposite the first.

An embodiment of the invention provides for a method to form a photovoltaic cell, the method comprising: providing a crystalline semiconductor lamina having a light-facing surface and a back surface, the lamina having a thickness of 50 microns or less, the lamina lightly doped to a first conductivity type; forming either a heavily doped region within the lamina at the light-facing surface or a heavily doped semiconductor layer on the lamina, the heavily doped region or layer doped to a second conductivity type opposite the first; forming an insulator layer above the lamina, the insulator layer having a thickness of about 40 angstroms or less; and forming a conductor above and in contact with the insulator layer.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view of a prior art photovoltaic cell.

FIGS. 2a-2d are cross-sectional views showing stages in formation of an embodiment of Sivaram et al., U.S. patent application Ser. No. 12/026,530.

FIG. 3 is a cross-sectional view of an embodiment of the present invention.

FIGS. 4a-4d are cross-sectional views showing stages of formation of embodiments of the present invention.

FIG. 5 is a cross-sectional view showing an embodiment of the present invention.

FIGS. 6 and 7 are cross-sectional view showing additional embodiments of the present invention.

FIGS. 8a and 8b are cross-sectional views showing stages of formation of still another embodiment of the present invention.

### DETAILED DESCRIPTION OF THE PREFERRED EMBODIMENTS

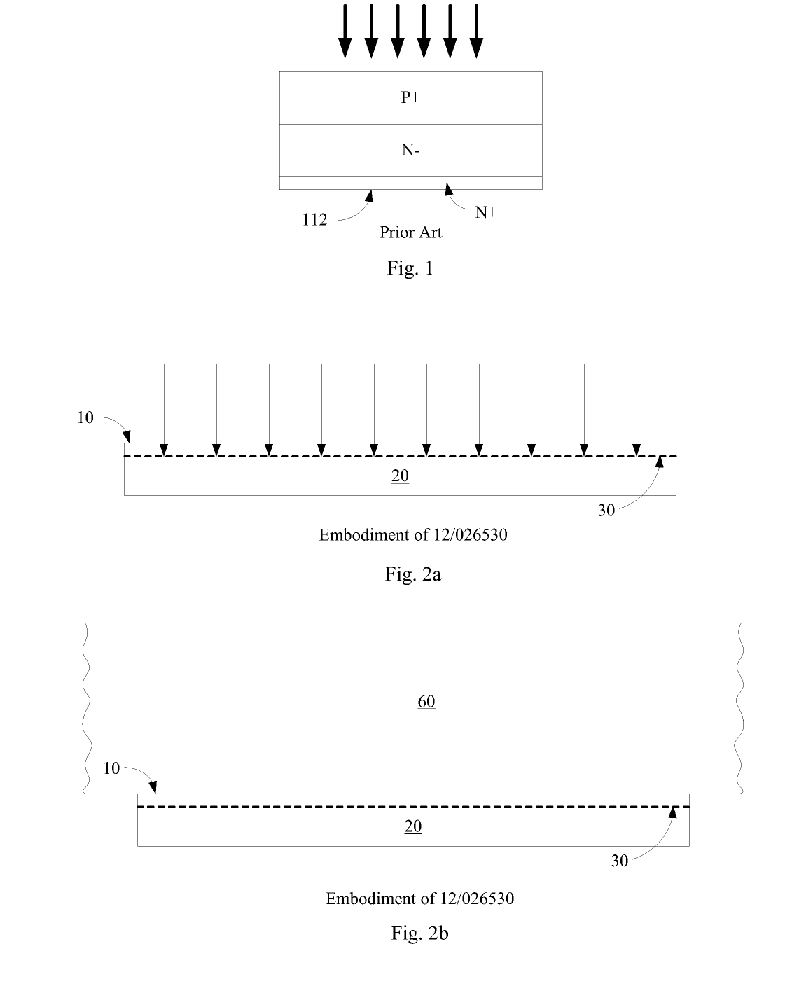

A conventional prior art photovoltaic cell includes a p-n diode; an example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a n−/p+ junction (as shown in FIG. 1) or a p−/n+ junction. The more lightly doped region is known as the base of the photovoltaic cell, while the more heavily doped region is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

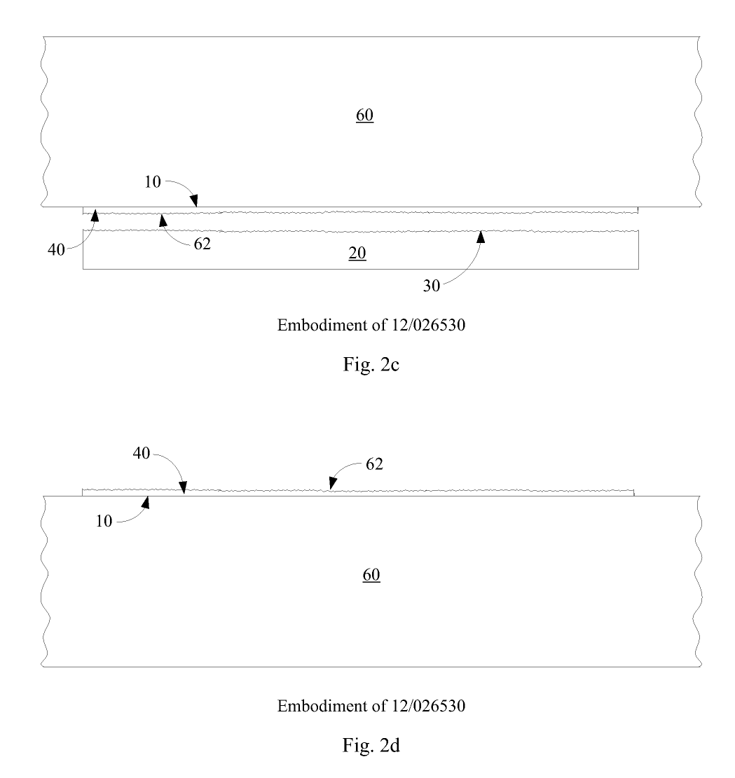

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted with one or more species of gas ions, for example hydrogen and/or helium ions. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick, though any thickness within the named range is possible. FIG. 2d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference.

Using the methods of Sivaram et al., rather than being formed from sliced wafers, photovoltaic cells are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

Conventional crystalline photovoltaic cells may be, for example, about 100 to 300 microns thick, and may have heavily doped regions formed on opposite faces of the wafer. Using conventional techniques, this cell structure is readily achieved: The wafer is doped as desired on each side, then is affixed to a substrate or superstrate once all high-temperatures steps are complete.

Referring to FIG. 2d, in many embodiments of Sivaram et al., heavily doped regions are also formed both at first surface 10 and at second surface 62 of the photovoltaic cell, in order to define a p-n junction and to provide ohmic contact to the cell. In embodiments of Sivaram et al. and Herner, the donor wafer is affixed to receiver element 60 before exfoliation so that receiver element 60 will provide mechanical support to thin lamina 40 during and after exfoliation. Lamina 40 may be very thin and will be prone to breakage during fabrication without this support. Doping of second surface 62, which is created by exfoliation, thus typically takes place while lamina 40 is bonded to receiver element 60. Formation of a heavily doped region at second surface 62 may require a high-temperature step to introduce and activate the dopant.

Exposing lamina 40 to a high-temperature step while it is bonded to receiver element 60 entails the risk of damage to receiver element 60; damage to the bond itself, of potential contamination to semiconductor lamina 40 by adjacent material, for example by metal or other conductive material at first surface 10; and of degradation of reflection quality in embodiments where a reflective layer is present between receiver element 60 and lamina 40. Careful selection of receiver and bonding materials may help reduce or eliminate this risk.

In the present invention, such damage is avoided by avoiding high temperature steps following exfoliation. As noted, a photovoltaic cell typically includes a p-n diode. It is known to use other types of diodes in photovoltaic cells, however, and by using other types of diodes, a high temperature doping step may be avoided.

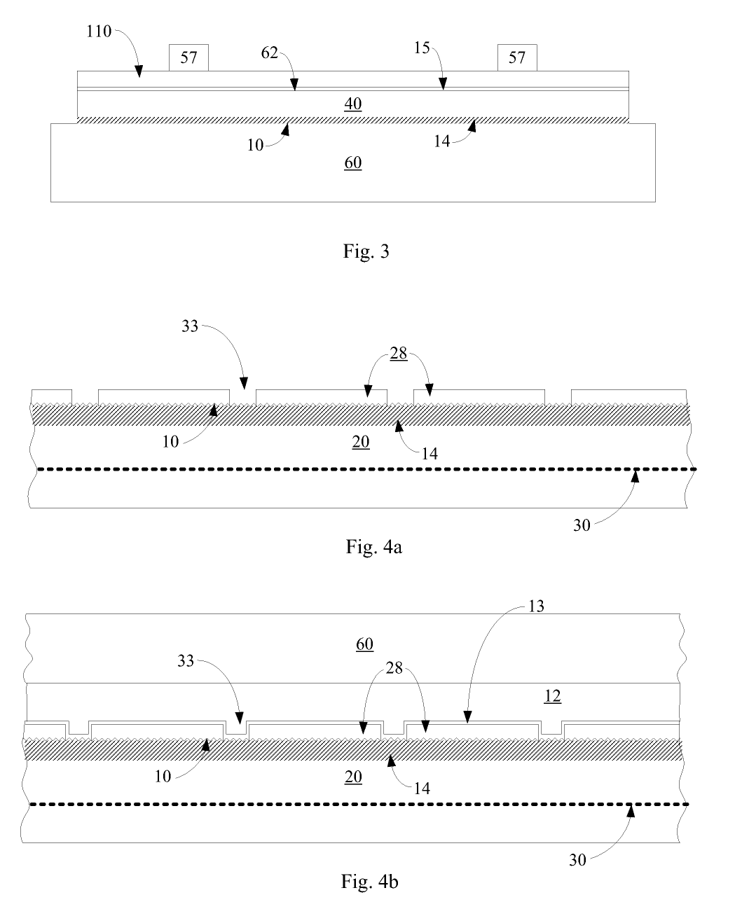

One such alternative diode type is a metal-insulator-silicon (MIS) diode. Turning to FIG. 3, a wafer (not shown) which is lightly doped to a first conductivity type is affixed to receiver element 60 at first surface 10, then lamina 40 is cleaved from the wafer at a previously defined cleave plane, creating second surface 62, as described earlier. As will be described in detailed examples provided below, one or more layers may be disposed between lamina 40 and receiver element 60. This example will describe the wafer, and thus lamina 40, as being n-doped, but it will be understood that, in this and other embodiments, conductivity types may be reversed. Before affixing to receiver element 60, first surface 10 may have been doped to form heavily n-doped region 14. Because the doping step to form heavily n-doped region 14 takes place before affixing and exfoliation, it can be performed at high temperatures with no risk of damage to the completed cell.

If a p-n diode were to be formed, in some embodiments it would then be necessary to perform a doping step to dope all or a portion of second surface 62, forming a p-type emitter. Such a step would typically require high temperature.

In the present invention, an MIS-type tunnel diode is formed instead. An insulator layer 15 is formed on or above second surface 62. Insulator layer 15 is thin enough to allow tunneling of charge carriers, for example about 30 angstroms or less. Insulator layer 15 is formed by a relatively low temperature method, such as plasma enhanced chemical vapor deposition (PECVD) or, alternatively, may be chemically grown, or grown by ozone oxidation of silicon. Ozone growth on silicon is described by Nishiguchi et al., “Rapid Oxidation of Silicon Using UV-Light Irradiation in Low-Pressure, Highly Concentrated Ozone Gas below 300° C.,” Japanese Journal of Applied Physics, 46, (2007) pp. 2835-2839. A conductive layer 110 is formed on insulator layer 15. In this example conductor 110 is a transparent conductive oxide (TCO), which also may be formed at low temperature. Wiring 57 may be formed on TCO 110 by a low-temperature method, as with silver screen print paste.

In this embodiment, the photovoltaic cell comprises a substantially crystalline semiconductor lamina having a first surface and a second surface opposite the first; a transparent conductive oxide; and an insulator layer having a thickness no more than about 40 angstroms, the insulator layer disposed between the lamina and the transparent conductive oxide. The semiconductor lamina is lightly doped to a first conductivity type, the second surface of the lamina is nearer the insulator layer and the first surface of the lamina is farther from the insulator layer, and the first surface of the lamina is heavily doped to the first conductivity type. During normal operation of the cell, charge carriers pass between the transparent conductive oxide and the lamina by tunneling through the insulator layer.

In other embodiments, the conductive layer may be a very thin layer of a metal or metal compound. If this layer is sufficiently thin, for example 200 angstroms or less, it will not impede passage of incident light into lamina 40. Lamina 40, insulator layer 15 and TCO 110 (or the thin metal layer if it is used instead) behave as an MIS-type tunnel diode. During normal operation of the cell, charge carriers pass between conductor 110 and lamina 40 by tunneling through insulator layer 15. Note that in FIG. 3, thicknesses of the various layers cannot practically be depicted to scale. As will be described, additional layers and structures may be included.

Note that the term MIS-type tunnel diode is used here to refer to a diode that has the same general electrical behavior and properties as a conventional MIS tunnel diode. The conductor in an MIS-type tunnel diode need not be an elemental metal, however, and may instead be a conductive metal compound, such as titanium nitride, or a conductive metal alloy, such as 90 percent titanium/10 percent tungsten, or a TCO. Advantageous TCOs include aluminum-doped zinc oxide, indium tin oxide, tin oxide, titanium oxide, etc.

For clarity, a detailed example of a photovoltaic cell comprising an MIS-type tunnel diode, and including a lamina having thickness between 0.2 and 100 microns according to embodiments of the present invention, will be provided. For completeness, many materials, conditions, and steps will be described. It will be understood, however, that many of these details can be modified, augmented, or omitted while the results fall within the scope of the invention. In these embodiments, it is described to cleave a semiconductor lamina by implanting gas ions and exfoliating the lamina. Other methods of cleaving a lamina from a semiconductor wafer could also be employed in these embodiments.

### EXAMPLE

### MIS-Type Tunnel Diode with TCO

The process begins with a donor body of an appropriate semiconductor material. An appropriate donor body may be a monocrystalline silicon wafer of any practical thickness, for example from about 200 to about 1000 microns thick. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline.

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with no unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

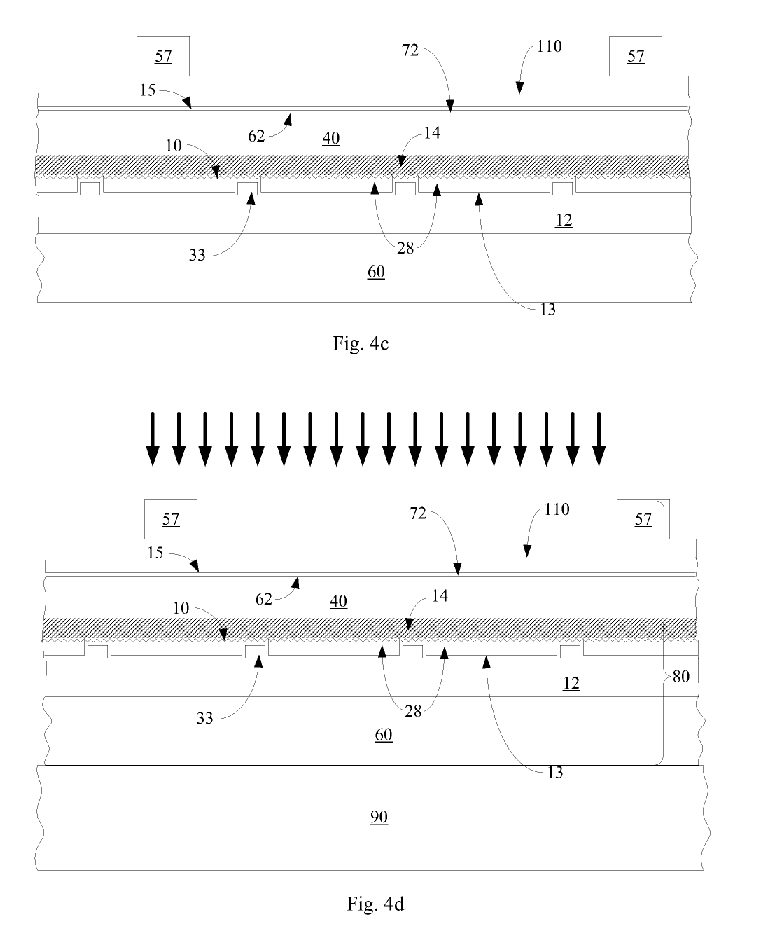

Referring to FIG. 4a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. The fact that donor wafer 20 can be reused for some other purpose following exfoliation of one or more laminae makes the use of higher-quality silicon economical. Donor wafer 20 may be semiconductor-grade silicon, rather than solar-grade silicon, for example.

First surface 10 of donor wafer 20 may be substantially planar, or may have some preexisting texture. If desired, some texturing or roughening of first surface 10 may be performed. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001. Methods to create surface roughness are described in further detail in Petti, U.S. patent application Ser. No. 12/130,241, “Asymmetric Surface Texturing For Use in a Photovoltaic Cell and Method of Making,” filed May 30, 2008; and in Herner, U.S. patent application Ser. No. 12/343,420, “Method to Texture a Lamina Surface Within a Photovoltaic Cell,” filed Dec. 23, 2008, both owned by the assignee of the present application and both hereby incorporated by reference.

First surface 10 may also be heavily doped to some depth to the same conductivity type as wafer 20, forming heavily doped region 14; in this example, heavily doped region 14 is n-type. As wafer 20 has not yet been affixed to a receiver element, high temperatures can be readily tolerated at this stage of fabrication, and this doping step can be performed by any conventional method, including diffusion doping, or deposition of doped glass followed by an anneal to drive in and activate the dopant. Any conventional n-type dopant may be used, such as phosphorus or arsenic. Dopant concentration may be as desired, for example at least 1×10¹⁸ dopant atoms/cm³, for example between about 1×10¹⁸ and 1×10²¹ dopant atoms/cm³. Doping and texturing can be performed in any order, but since most texturing methods remove some thickness of silicon, it may be preferred to form heavily doped n-type region 14 following texturing. Doping is followed by conventional deglazing.

Next, a dielectric 28 is formed on first surface 10. As will be seen, in the present example, first surface 10 will be the back of the completed photovoltaic cell, and a reflective, conductive material is to be formed on the dielectric layer. The reflectivity of the conductive layer to be formed is enhanced if dielectric layer 28 is relatively thick. For example, if dielectric layer 28 is silicon dioxide, it may be between about 1000 and about 1500 angstroms thick, while if dielectric layer 28 is silicon nitride, it may be between about 700 and about 800 angstroms thick, for example about 750 angstroms, creating a quarter wave plate. This layer may be grown or deposited. A grown oxide or nitride layer 28 passivates first surface 10 better than if this layer is deposited. In some embodiments, a first thickness of layer 28 may be grown, while the rest is deposited.

In the next step, ions, preferably hydrogen or a combination of hydrogen and helium, are implanted through dielectric layer 28 into wafer 20 to define a cleave plane 30, as described earlier. The cost of this hydrogen or helium implant may be kept low by methods described in Parrill et al., U.S. patent application Ser. No. 12/122,108, “Ion Implanter for Photovoltaic Cell Fabrication,” filed May 16, 2008, owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns or between about 1 or 2 microns and about 5 microns.

After implant, openings 33 are formed in dielectric 28 by any appropriate method, for example by laser scribing or screen printing. The size of openings 33 may be as desired, and will vary with dopant concentration, metal used for contacts, etc. In one embodiment, these openings may be about 40 microns square.

Turning to FIG. 4b, a layer 13 of a conductive barrier material is deposited next on dielectric layer 28, filling openings 33 and contacting heavily doped region 14 in openings 33 at first surface 10. Possible materials for this layer include tantalum, titanium, titanium nitride, a titanium/tungsten alloy or a stack of appropriate materials, for example titanium and titanium nitride. Barrier layer 13 may be, for example, about 1000 angstroms thick or more. Next a layer 12 of a conductive material is formed, for example aluminum, silver, copper, titanium, chromium, molybdenum, tantalum, zirconium, vanadium, indium, cobalt, antimony, or tungsten, or alloys thereof, or any other suitable material. Conductive layer 12 may be a stack of conductive materials. In one embodiment, conductive layer 12 is a thick layer, for example about three microns or more, of aluminum. Barrier layer 13 serves to prevent reaction between conductive layer 12 and silicon, which may contaminate the lamina to be formed and compromise cell efficiency. In some embodiments, barrier layer 13 may be omitted.

Next, wafer 20 is affixed to a receiver element 60, with dielectric layer 28, conductive barrier layer 13, and conductive layer 12 intervening. Receiver element 60 may be any suitable material, including glass, such as soda-lime glass or borosilicate glass; a metal or metal alloy such as stainless steel or aluminum; a polymer; or a semiconductor, such as metallurgical grade silicon. The wafer 20, receiver element 60, and intervening layers are bonded by any suitable method. If receiver element 60 is soda-lime glass, anodic bonding may be advantageous. In most embodiments, receiver element 60 has a widest dimension no more than about twenty percent greater than the widest dimension of wafer 20, and in most embodiments the widest dimension may be about the same as that of wafer 20.

Referring to FIG. 4c, which shows the structure inverted with receiver element 60 on the bottom, a thermal step causes lamina 40 to cleave from donor wafer 20 at the cleave plane. In some embodiments, this cleaving step may be combined with a bonding step. Cleaving is achieved in this example by exfoliation, which may be performed at temperatures between, for example, about 350 and about 550 or 650 degrees C. In general exfoliation proceeds more rapidly at higher temperature. The thickness of lamina 40 is determined by the depth of cleave plane 30. In many embodiments, the thickness of lamina 40 is between about 1 and about 10 microns, for example between about 2 and about 5 microns. Bonding and exfoliation may be achieved using methods described in Agarwal et al., U.S. patent application Ser. No. 12/335,479, “Methods of Transferring a Lamina to a Receiver Element,” filed Dec. 15, 2008, owned by the assignee of the present application and hereby incorporated by reference.

Second surface 62 has been created by exfoliation. Sufficient texturing may exist at second surface 62 upon exfoliation. If desired, an additional texturing step may be performed at second surface 62 by any of the methods described earlier. Such a texturing step may serve to remove damage at second surface 62. A specific damage-removal step may be performed, for example by chemical etch or plasma treatment. Damage removal and texturing may be a combined step, or may be separate steps.

After cleaning, a thin layer 72 of intrinsic amorphous silicon is optionally deposited on second surface 62. This layer serves to passivate dangling bonds at second surface 62 of lamina 40. Such dangling bonds may cause unwanted recombination of charge carriers, compromising conversion efficiency. Layer 72 will be quite thin, for example less than about 30 angstroms thick, for example between about 10 and about 30 angstroms thick, for example between about 15 and about 20 angstroms thick. In some embodiments intrinsic amorphous silicon layer 72 may be omitted. Amorphous silicon layer 72 is formed by any conventional method, for example plasma-enhanced chemical vapor deposition (PECVD). This PECVD step is performed at relatively low temperature, for example about 300 degrees C. or less.

Next a thin insulator layer 15 is formed on amorphous layer 72, or directly on second surface 62 if amorphous layer 72 was omitted. Insulator layer 15 should be less than about 40 angstroms thick, thin enough to allow tunneling of charge carriers. In most embodiments, the thickness of insulator layer 15 will be 30 angstroms or less, for example about 10, 15 or 20 angstroms. Insulator layer 15 will be any appropriate insulator, for example silicon dioxide or aluminum oxide. In some embodiments, insulator layer 15 may be a stack of more than one insulating material, though the combined thickness of the stack must be thin enough to allow tunneling of charge carriers. Ideally the combined thickness of insulator 15 and intrinsic amorphous silicon layer 72 is about 30 angstroms or less. Thermal oxides are generally of higher quality than deposited oxides, but, in order to keep processing temperature low, insulator layer 15 may be deposited by a low-temperature method, for example by plasma-enhanced CVD (PECVD). Deposition of silicon dioxide by PECVD may take place at, for example, about 250 to about 400 degrees C.

In this embodiment a TCO layer 110 is formed directly on and in immediate contact with insulator layer 15. Appropriate materials for TCO 110 include aluminum-doped zinc oxide, as well as indium tin oxide, tin oxide, titanium oxide, etc. In alternative embodiments, an additional antireflective layer (not shown) may be formed on top of TCO 110. The thickness of TCO 110 may be, for example, between about 800 and about 1000 angstroms, though may be thicker or thinner if desired. Finally, in some embodiments wiring 57 is formed on TCO 110 by any suitable method. Wiring 57 may be formed of, for example, silver screen print paste. Silver screen-printed paste can be selected having curing temperature of 600 degrees C. or less. If amorphous silicon layer 72 is present, temperature should be kept still lower to avoid crystallizing this layer. Polymer silver screen print paste can be cured at temperatures below 300 or 250 degrees C.

FIG. 4d shows completed photovoltaic assembly 80 which includes lamina 40 and receiver element 60, and includes a completed photovoltaic cell. Photovoltaic assembly 80, along with a plurality of other photovoltaic assemblies 80, can be mounted on supporting substrate 90, as shown, forming a photovoltaic module. In an alternative embodiment, photovoltaic assemblies 80 can be affixed to a transparent superstrate, not shown. Incident light enters lamina 40 at second surface 62, and, after traveling through lamina 40, is reflected back into lamina 40 at first surface 10. The photovoltaic cells of the photovoltaic assemblies 80 can be attached electrically in series, for example using the methods described in Petti et al., “Front Connected Photovoltaic Assembly,” U.S. patent application Ser. No. 12/331,376, hereinafter the '376 application, filed Dec. 9, 2008, owned by the assignee of the present application and hereby incorporated by reference.

The photovoltaic cell just described comprises a substantially crystalline lamina having a light-facing surface and a back surface, the lamina having a thickness of about 50 microns or less; an insulator layer having a thickness no more than about 40 angstroms, the insulator layer disposed above the light-facing surface of the lamina; and a conductor disposed above the insulator layer and in immediate contact with the insulator layer. The lamina, the insulator layer and the conductor operate as an MIS-type tunnel diode. Note in most embodiments the insulator layer is disposed between silicon (either the lamina or an amorphous silicon layer, for example) and the conductor, and is in immediate contact with both.

### Selected Alternative Embodiments

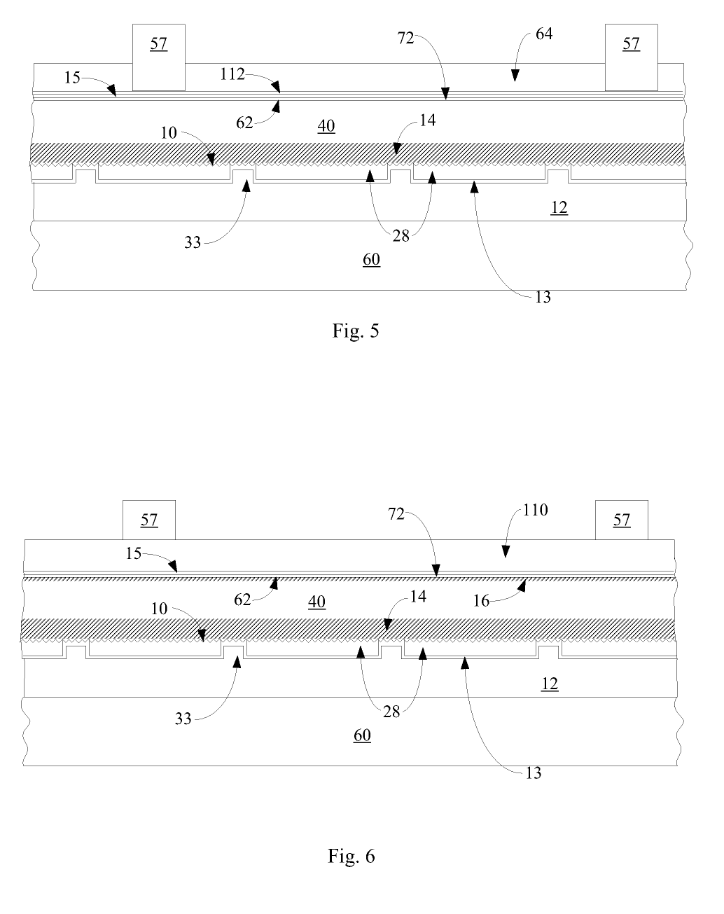

For clarity and completeness, a detailed example has been provided, but many alternatives exist. In the example just provided, referring to FIG. 4d, the MIS-type tunnel diode was formed by semiconductor lamina 40, insulator layer 15, and TCO 110. In an alternative embodiment, turning to FIG. 5, TCO 110 can be replaced by a very thin metal layer 112. This metal layer 112 is thick enough to electrically replace TCO 110 to form an MIS-type tunnel diode with insulator layer 15 and lamina 40, but is thin enough to be substantially transparent. Metal layer 112 can be any appropriate metal or metal compound, for example, gold, platinum, aluminum, nickel, chromium, or silver. The thickness of metal layer 112 can be about 200 angstroms or less. For example this thickness may be about 50 and about 200 angstroms, for example between about 80 and about 120 angstroms, in some embodiments about 100 angstroms. Metal layer 112 can be formed by any appropriate method, for example sputtering or evaporation. An antireflective coating (ARC) 64 is formed on metal layer 112. A thickness of, for example, about 700 to 800 angstroms of silicon nitride is commonly used as an ARC, though any suitable material may be substituted.

Openings are created in ARC 64 exposing portions of metal layer 112. These openings may be created by various methods, including screen printing or laser ablation; thus the width of these openings may range from about 15, 20, 25, or 50 microns to about 75, 80, 100, 110 microns or more.

Next wiring 57 is formed in the openings. Wiring 57 can be formed by a variety of methods. When the openings and wiring 57 are to be relatively narrow, for example less than 75 microns, wiring may advantageously be formed by electroless plating. For example, in one embodiment, formation of a very thin nickel seed layer (not shown) on the exposed regions of metal layer 112 is followed by electroplating of copper, or, for example, conventional or light-induced plating of either silver or copper. These plating methods selectively deposit the metal, forming wiring 57. The thickness of wiring 57 will be selected to produce the desired resistance. In other embodiments, wiring 57 may be formed by other methods, for example screen printing, or, alternatively, aerosol-jet printing or inkjet printing. Various methods for fabricating wiring, which might be employed in any of the embodiments disclosed herein, are described in Hilali et al., U.S. patent application Ser. No. 12/189,157, “Photovoltaic Cell Comprising a Thin Lamina Having Low Base Resistivity and Method of Making,” filed Aug. 10, 2008; and in Hilali et al., U.S. patent application Ser. No. 12/339,032, “Method For Making a Photovoltaic Cell Comprising Contact Regions Doped Through a Lamina,” filed Dec. 18, 2008, both owned by the assignee of the present application and both hereby incorporated by reference.

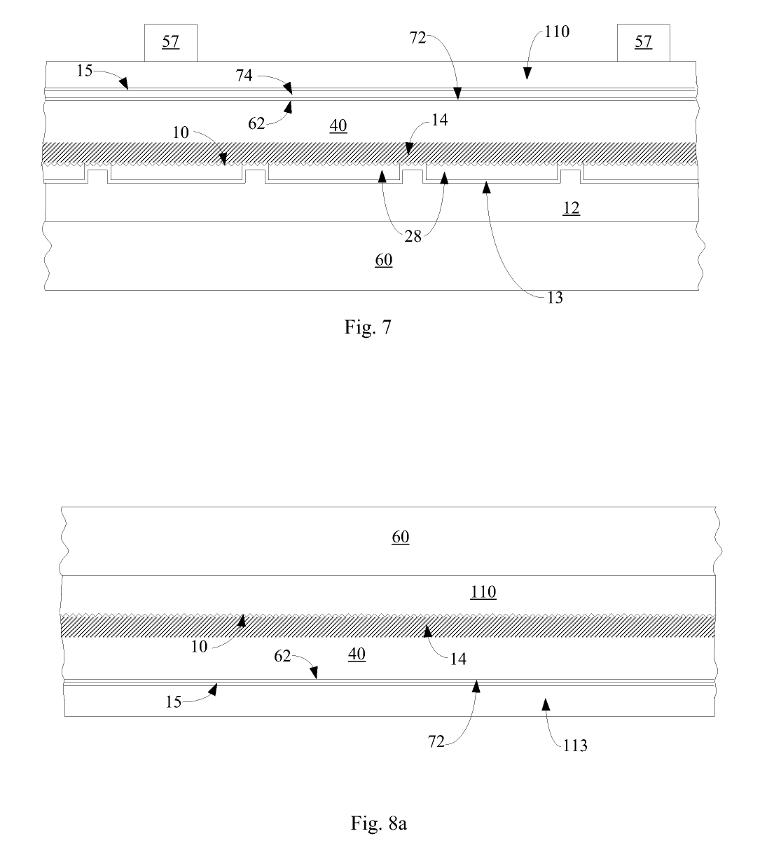

In some embodiments, it may be preferred to form a very thin silicon region at or near the second surface 62, which is doped to the opposite conductivity type as lamina 40. Such a structure may be formed in various ways. Referring to FIG. 6, in one embodiment, fabrication proceeds as in the prior embodiment to the point at which lamina 40 is cleaved from the donor wafer, creating second surface 62. After any treatment of second surface 62, to texture, clean, and/or remove damage, a material that will provided a dopant of a conductivity type opposite that of lamina 40 is applied to second surface 62. A dopant source is spun or sprayed onto second surface 62, baked at low temperature, for example about 200 degrees C., then annealed at less than 725 degrees C., for example about 600 to 700 degrees C. for about one minute, creating a very shallow doped region 16 at second surface 62. Use of a spin-on dopant source is described by Usami et al., “Shallow-Junction Formation on Silicon by Rapid Thermal Diffusion of Impurities from a Spin-on Source,” IEEE Transactions on Electron Devices, vol. ED 39, 1992, pp. 105. Note that the most effective dopant sources for this technique provide phosphorus, which is an n-type dopant. Typically the depth of heavily doped region 16 extends no more than about 50 nm from second surface 62. To use such a phosphorus source to form heavily doped region 16, then, which should be doped to the opposite conductivity type as lamina 40, the conductivity types should be reversed from the prior example: The donor wafer, and thus lamina 40, should be lightly p-doped, with heavily doped p-type region 14 formed at first surface 10. Heavily doped n-type region at second surface 62 is n-type. From this point, fabrication of the cell proceeds as in the prior example, with fabrication of optional intrinsic amorphous silicon layer 72, insulator layer 15, and a conductor, either TCO 110 (as shown) or a metal layer (not shown) completing the MIS-type tunnel diode.

An alternative embodiment which includes a layer doped to the opposite conductivity type as lamina 40 is shown in FIG. 7. Fabrication again proceeds as in the original example, to the point at which lamina 40 is cleaved from the donor wafer, creating second surface 62. After any treatment of second surface 62, to texture, clean, and/or remove damage, intrinsic amorphous layer 72 is optionally deposited on second surface 62, having the same thickness as described earlier. Next a heavily doped amorphous silicon layer 74 is deposited on intrinsic amorphous layer 72, or directly on second surface 62 if intrinsic amorphous layer 72 was omitted. Typically heavily doped amorphous layer 74 will be 50 angstroms thick or less. Note that in embodiments in which a heavily doped amorphous layer serves as an emitter in a p-n diode cell, rather than as a layer in an MIS-type tunnel diode, this layer is considerably thicker, generally at least 200 or 300 angstroms. Heavily doped amorphous silicon layer 74 is doped during deposition, by providing dopant atoms as the amorphous silicon forms, and thus can readily be doped to either conductivity type. Thus if lamina 40 is n-type, heavily doped amorphous silicon layer 74 is p-type, and vice versa. Cell fabrication proceeds as before; insulator layer 15 is formed on heavily doped amorphous silicon layer 74, and TCO 110 is formed on insulator layer 15, completing the MIS-type tunnel diode. As described earlier, in alternative embodiments, a metal layer and ARC can replace TCO 110.

Note that the role of heavily doped region 16, in FIG. 6, or of heavily doped amorphous layer 74, in FIG. 7, is to decrease recombination at the insulator-silicon interface and to improve minority carrier collection, thus improving open circuit voltage. Despite the presence of this oppositely doped layer, however, the cell does not behave as a p-n diode. Even with this doped layer present, the lamina, insulator, and conductor (TCO or metal) behave as an MIS-type tunnel diode.

In the embodiments just described, a photovoltaic cell includes a substantially crystalline semiconductor lamina having a light-facing surface and a back surface, wherein the lamina is lightly doped to a first conductivity type, and comprises a region at the back surface heavily doped to the first conductivity type; an uninterrupted insulator layer having a thickness no more than about 40 angstroms, the insulator layer disposed above the light-facing surface of the lamina; and a transparent conductive oxide disposed above and in immediate contact with the insulator layer. As described, either the lamina further comprises a region at the light-facing surface heavily doped to a second conductivity type opposite the first, or the photovoltaic cell further comprises a heavily doped semiconductor layer above the light-facing surface of the lamina, the heavily doped semiconductor layer doped to a second conductivity type opposite the first. In neither case does processing temperature exceed about 725 degrees C. during these steps. Note that in the embodiments of FIGS. 6 and 7, second surface 62 is the light-facing surface, while first surface 10 is the back surface.

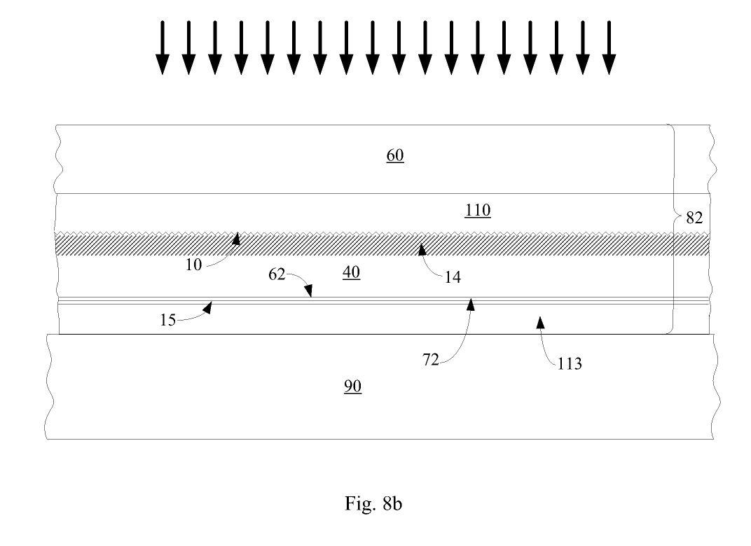

In the embodiments described so far, the receiver element has served as a substrate in the finished device. In other embodiments, the receiver element may serve as a superstrate. Referring to FIG. 8a, a donor wafer (not shown), in this example lightly n-doped, is optionally doped to form heavily n-doped region 14 at first surface 10. An ion implantation step, as described earlier, defines a cleave plane in the donor wafer. A TCO 110 is deposited on first surface 10, then the wafer is bonded to receiver element 60 with TCO 110 disposed between them. Receiver element 60 will serve as a superstrate; thus it must be transparent. Any suitable material may be used for receiver element 60, including borosilicate glass or soda-lime glass.

As in prior embodiments, lamina 40 is cleaved from the donor wafer, creating second surface 62. Fabrication continues as in prior embodiments: Optional intrinsic amorphous silicon layer 72 is formed on second surface 62, followed by insulator layer 15. These layers may be formed of the materials and by the methods described in earlier embodiments. Metal layer 113 completes the MIS tunnel diode. Recall that in this embodiment, receiver element 60 will serve as a superstrate, and that incident light will enter lamina 40 at first surface 10. Unlike in prior embodiments, then, metal layer 113 will be at the back of the cell. Thus metal layer 113 need not be transparent, and in fact is preferably reflective. Metal layer 113 may be aluminum, for example, or a stack of metal or other conductive materials. Recall that in some prior embodiments, if aluminum was used as a conductor, a barrier layer was formed between the silicon of lamina 40 and the aluminum layer to prevent them from reacting. In this case, however, there are generally no high-temperature steps following deposition of aluminum layer 113, so there is no danger of such reaction and the barrier layer may be omitted. In an alternative embodiment, conductive layer 113 may be a TCO with a reflective layer formed at the back surface of the cell. The thickness of the TCO may be selected such that it serves as a quarter wave plate, enhancing reflectivity.

Turning to FIG. 8b, completed photovoltaic assembly 82 includes lamina 40 and receiver element 60, and includes a completed photovoltaic cell. Photovoltaic assembly 82, along with a plurality of other photovoltaic assemblies 82, can be mounted on supporting substrate 90, as shown, forming a photovoltaic module. In an alternative embodiment, photovoltaic assemblies 82 can be affixed to a transparent superstrate, not shown. As indicated by arrows, incident light enters lamina 40 at first surface 10, and, after traveling through lamina 40, is reflected back into lamina 40 at second surface 62. The photovoltaic cells of the photovoltaic assemblies 82 can be attached electrically in series, for example using the methods described in the '376 application.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A photovoltaic cell comprising:
a substantially crystalline semiconductor lamina having a first surface and a second surface opposite the first;
a transparent conductive oxide; and
an insulator layer having a thickness no more than about 40 angstroms, the insulator layer disposed between the lamina and the transparent conductive oxide,
wherein the semiconductor lamina is lightly doped to a first conductivity type, the second surface of the lamina is nearer the insulator layer and the first surface of the lamina is farther from the insulator layer, and the first surface of the lamina is heavily doped to the first conductivity type, and
wherein, during normal operation of the cell, charge carriers pass between the transparent conductive oxide and the lamina by tunneling through the insulator layer.

2. The photovoltaic cell of claim 1 further comprising an amorphous silicon layer between the lamina and the insulator layer.

3. The photovoltaic cell of claim 1 wherein the lamina has a thickness between about 0.5 and about 20 microns.

4. The photovoltaic cell of claim 1 wherein the first surface of the lamina is doped to a concentration of at least about 1×10¹⁸ atoms/cm³.

5. The photovoltaic cell of claim 1 wherein the lamina is monocrystalline silicon.

6. The photovoltaic cell of claim 1 wherein, during normal operation of the cell, the first surface is the back surface of the lamina.

7. A photovoltaic cell comprising:
a substantially crystalline lamina having a light-facing surface and a back surface, the lamina having a thickness of about 50 microns or less;
an insulator layer having a thickness no more than about 40 angstroms, the insulator layer disposed above the light-facing surface of the lamina; and
a conductor disposed above the insulator layer and in immediate contact with the insulator layer.

8. The photovoltaic cell of claim 7 wherein, during normal operation of the cell, the lamina, the insulator layer, and the conductor operate as an MIS-type tunnel diode.

9. The photovoltaic cell of claim 7 wherein the lamina thickness is between about 0.5 and about 20 microns.

10. The photovoltaic cell of claim 7 wherein the insulator layer is disposed between silicon and the conductor and is in immediate contact with both.

11. The photovoltaic cell of claim 10 wherein the silicon is amorphous silicon in immediate contact with the lamina.

12. The photovoltaic cell of claim 11 wherein the lamina is doped to a first conductivity type, and at least some of the amorphous silicon is heavily doped to a second conductivity type opposite the first.

13. The photovoltaic cell of claim 7 wherein the conductor is a transparent conductive oxide.

14. The photovoltaic cell of claim 7 wherein the conductor is a metal or metal compound layer having a thickness of 200 angstroms or less.

15. A photovoltaic cell comprising:
a substantially crystalline semiconductor lamina having a light-facing surface and a back surface, wherein the lamina is lightly doped to a first conductivity type, and comprises a region at the back surface heavily doped to the first conductivity type;
an uninterrupted insulator layer having a thickness no more than about 40 angstroms, the insulator layer disposed above the light-facing surface of the lamina; and
a transparent conductive oxide disposed above and in immediate contact with the insulator layer,
wherein either the lamina further comprises a region at the light-facing surface heavily doped to a second conductivity type opposite the first, or the photovoltaic cell further comprises a heavily doped semiconductor layer above the light-facing surface of the lamina, the heavily doped semiconductor layer doped to a second conductivity type opposite the first.

16. The photovoltaic cell of claim 15 wherein the lamina comprises a region at the light-facing surface heavily doped to a second conductivity type opposite the first, wherein the depth of the heavily doped region extends no more than about 50 nm from the light-facing surface.

17. The photovoltaic cell of claim 15 wherein the lamina has a thickness between about 0.5 and about 50 microns.

18. The photovoltaic cell of claim 15 wherein the insulator layer comprises silicon dioxide, aluminum oxide, or both.

19. A method to form a photovoltaic cell, the method comprising:
providing a crystalline semiconductor lamina having a light-facing surface and a back surface, the lamina having a thickness of 50 microns or less, the lamina lightly doped to a first conductivity type;
forming either a heavily doped region within the lamina at the light-facing surface or a heavily doped semiconductor layer on the lamina, the heavily doped region or layer doped to a second conductivity type opposite the first;
forming an insulator layer above the lamina, the insulator layer having a thickness of about 40 angstroms or less; and
forming a conductor above and in contact with the insulator layer.

20. The method of claim 19 wherein, during the step of forming either a heavily doped region or a heavily doped layer, processing temperature does not exceed about 725 degrees C.

21. The method of claim 19 wherein the step of forming either a heavily doped region or a heavily doped layer comprises spraying a dopant source on the light-facing surface and annealing at a temperature of about 725 degrees C. or less to form the heavily doped region.

22. The method of claim 19 wherein the step of forming either a heavily doped region or a heavily doped layer comprises depositing the heavily doped layer of amorphous silicon.

23. The method of claim 22 further comprising depositing an intrinsic layer of amorphous silicon before depositing the heavily doped layer of amorphous silicon.
